(19) United States
(12) Patent Application Publication
(10) Pub. No.: US 2004/0200522 A1
(43) Pub. Date: Oct. 14, 2004

(54) Solar cell element and solar cell module

(75) Inventors: Yuko Fukawa, Yokaichi-shi (JP); Shuichi Fujii, Yokaichi-shi (JP); Takashi Tsuge, Ise-shi (JP)

Correspondence Address: HOGAN & HARTSON L.L.P., 500 S. GRAND AVENUE, SUITE 1900, LOS ANGELES, CA, 90071-2611, US

(73) Assignee: KYOCERA CORPORATION

(21) Appl. No.: 10/801,987

(22) Filed: Mar. 16, 2004

(30) Foreign Application Priority Data
Mar. 17, 2003 (JP) JP 2003-72347
Mar. 17, 2003 (JP) JP 2003-72350
Mar. 27, 2003 (JP) JP 2003-87433

(51) Int. Cl. H01L 31/00

(52) U.S. Cl. 136/259; 136/256

(57) ABSTRACT

There is disclosed a solar cell element which comprises a semiconductor substrate 1; an antireflective film 3 formed on a light-receiving surface of the semiconductor substrate 1; a surface electrode 5 formed on the light-receiving surface of the semiconductor substrate 1; a back surface electrode 6 formed on a non-light receiving surface of the semiconductor substrate; a first solder layer 8 covering the surface electrode 5; and a second solder layer 9 covering the back surface electrode 6. Two or more elements selected from a plurality of elements included in the surface electrode 5 and two or more elements selected from a plurality of elements included in the first solder layer 8 are each identical to one another, which are, for example, Ag and Ti or P. The adhesion strength between the electrode and solder can be enhanced by this arrangement.

This application is based on applications Nos. 2003-87433, 2003-72347 and 2003-72350 filed in Japan, the content of which is incorporated hereinto by reference.

### BACKGROUND OF THE INVENTION

1. Field of the Invention

The present invention relates to a solar cell element with electrodes coated with solder.

The present invention also relates to a solar cell module comprising a plurality of solar cell elements connected to one another by means of connection electrodes (hereinafter referred to as the “connection tabs”).

2. Description of the Related Art

A common conventional solar cell element is constructed, for example, such that a surface of a p-type semiconductor substrate is formed with a diffusion layer including an n-type impurity diffused to a certain depth, and an antireflective film comprising silicon nitride or the like is provided on the surface of the diffusion layer, and a surface electrode is further provided to be in contact with the diffusion layer. In addition, the back surface of the semiconductor substrate is formed with a BSF (Back Surface Field) layer that is a p-type diffusion layer with high impurity concentration, and a back surface electrode that forms an ohmic contact with the BSF layer is further provided.

Furthermore, a surface solder layer and back surface solder layer are formed on the surfaces of the surface electrode and the back surface electrode, respectively.

The surface electrode of this solar cell element is formed by applying the material for the surface electrode over the antireflective film followed by firing to cause the antireflective film to be fused, thereby bringing the surface electrode material into direct contact with the semiconductor substrate, which is the so-called firing-through process.

The back surface electrode of the solar cell element is formed by a process in which a paste composed mainly of aluminum is applied over most of the area of the back surface of the semiconductor substrate except a part thereof and dried, then a paste composed mainly of silver is applied so as to cover the part that is not coated with the paste containing aluminum and its periphery and dried, and finally, the paste composed mainly of silver is applied also on the surface side of the semiconductor substrate and dried, and then they are fired simultaneously, that is, the co-firing process.

In order to maintain the stable ohmic contact of the electrodes fabricated by these processes and to provide the electrodes with sufficient strength withstanding in a module, there are times when one or a plurality of powders selected from the group consisting of Ti, Bi, Co, Zn, Zr, Fe, Cr powders and oxide powders thereof are included in the electrode material fired onto the antireflective film.

Alternatively, a phosphorus compound may be included in the electrode material fired onto the antireflective film. Typical phosphorus compounds include phosphorus oxides such as P₂O₅ and P₂O₄, and Ag₃PO₄, silver pyrophosphate and the like.

However, the inclusion of additives in the electrode material in the above described ways often poses problems such as brittle electrodes, weakened adhesion between the electrodes and solder layers formed thereon, and poor wettability of the solder.

Since a single solar cell element provides only a small power output, usually a plurality of solar cell elements are connected in series/parallel so as to constitute a solar cell module so that practical electric power is generated from the solar cell module.

The connection between the solar cell elements is accomplished by electrically connecting the surface electrode on the light-receiving surface side of a solar cell element to the back surface electrode on the non-light receiving surface side of another solar cell element adjacent to the foregoing solar cell element by means of connection tabs.

For soldering the connection tabs used for interconnecting the solar cell elements, solders of the same composition are used for connection to the surface electrode on the light-receiving surface side and for connection to the back surface electrode on the non-light receiving surface side.

For this reason, when a connection tab on the light-receiving surface is first connected and a connection tab on the non-light receiving surface is thereafter heated for connection, there are times when the temperature of the connection tab on the opposite, light-receiving side that has been already soldered rises causing the solder to remelt, and as a result, the connection tab on the light-receiving side that has been connected peels off from the solar cell element. Or, even when it does not peel off, it is possible that the resistance component becomes so great that it affects the output of solar cell module. If the connection tab is reconnected, the joint strength drops due to the influence of the oxide layer of the solder and the like.

Similar problems arise also when a connection tab on the non-light receiving surface side is first connected.

In addition, it has been impossible to judge the state of soldering between the electrodes of the solar cell element and the connection tabs from the exterior appearance. Accordingly, it has been impossible to discover any defects even when the state of soldering between the electrodes of the solar cell element and the connection tabs is imperfect because of factors such as insufficient heat application in soldering for connecting the electrodes of the solar cell element to the connection tabs, or the connection tabs being detached from the electrodes.

When the state of soldering between the electrodes of the solar cell element and the connection tabs is imperfect, the joint strength between the connection tabs and the electrodes may drop causing the connection tabs to peel off from the electrodes in a later process, or the part where the state of soldering is imperfect may serve as electrical resistance, which leads to lowering of the output of the solar cell module.

This applies not only to the connections between the electrodes and connection tabs, but also to the connections between the connection tabs and a common connection line, as well as to the connections between the output wires from the solar cell element and the terminals within the terminal box.

An object of the present invention is to provide a high performance solar cell element that is free from output power degradation by enhancing the adhesion between the electrodes and solder layers formed thereon.

Another object of the present invention is to provide a high performance solar cell module that is free from output power degradation, in which connections within the solar cell module are implemented such that the joint strength between the electrodes of the solar cell elements and connection tabs is enhanced.

A still another object of the present invention is to provide a solar cell module with high reliability, in which connections within the solar cell module are implemented so as to permit visual inspection of the states of soldering at connection areas that are otherwise impossible to observe from the outside.

### BRIEF SUMMARY OF THE INVENTION

A solar cell element according to the present invention comprises: a semiconductor substrate; an antireflective film formed on a light-receiving surface of the semiconductor substrate; a surface electrode formed on the light-receiving surface of the semiconductor substrate; a back surface electrode formed on a non-light receiving surface of the semiconductor substrate; a first solder layer covering the surface electrode; and a second solder layer covering the back surface electrode, wherein two or more elements selected from a plurality of elements included in the surface electrode and two or more elements selected from a plurality of elements included in the first solder layer are each identical to one another.

Since the surface electrode and the first solder layer covering the surface electrode include the same elements in common and the number thereof is two or more in the foregoing solar cell element, wettability between the electrode and the solder layer is enhanced, resulting in improved adhesion strength.

It is preferred that one of the two or more elements is Ag, and the other elements are one or plural kinds selected from Ti, P and compounds thereof.

By selecting the elements included in the solder in such a manner, a good ohmic contact can be achieved even by the so-called firing through process in which the electrode material is directly applied over the antireflective film and fired to cause the antireflective film to be fused, thereby bringing the semiconductor substrate and the surface electrode into direct contact with each other. In addition, the surface electrode can be provided with sufficient adhesion strength that can withstand in a module. Moreover, the addition of the foregoing elements does not adversely affect the properties of the solder, while long-term reliability required for the solder can be maintained.

The first solder layer preferably includes 10-100 ppm of one or more kinds selected from Ti, P, and compounds thereof. Since this improves wettability between the electrode and solder, enhances the adhesion strength, and minimizes brittleness of the solder to ensure long-term reliability, connection to inner leads (connection tabs) can be accomplished in good order in a later process.

The aforementioned other elements are preferably included in the surface electrode at 0.05 to 5% by weight. This permits the surface electrode to have sufficient strength and minimizes wire resistance of the electrode material, so that a good ohmic contact can be achieved even by the firing through process in which the electrode material is applied directly over the antireflective film and fired onto it. In addition, the surface electrode can be provided with sufficient adhesion strength that can withstand in a module.

Since the solders are not limited to any particular kind in the present invention, the effect can be achieved with various kinds of solders. Not only Sn—Pb based solders can be used, but also so-called lead-free solders including Sn—Ag based solders, Sn—Ag—Bi based solders and Sn—Ag—Cu based solders that are prone to have problems in wettability and adhesion strength between electrode and solder can be used, so that the wettability and adhesion strength between electrode and solder can be enhanced.

Moreover, according to the present invention, wettability and adhesion strength between electrode and solder can also be enhanced when the surface electrode is formed by processes other than the firing through process.

A solar cell module according to the present invention comprises: solar cell elements each including a semiconductor substrate, a surface electrode formed on a light-receiving surface of the semiconductor substrate and a back surface electrode formed on a non-light receiving surface of the semiconductor substrate; and connection tabs for interconnecting the surface electrodes on the light-receiving surface and the back surface electrodes on the non-light receiving surface of the solar cell elements, wherein a first solder layer for connecting the surface electrodes to the connection tabs on the light-receiving surface and a second solder layer for connecting the back surface electrodes to the connection tabs on the non-light receiving surface have different melting points.

With the foregoing arrangement, since the connection tabs on the side of the light-receiving surface and the connection tabs on the side of the non-light receiving surface are each connected to the respective electrodes of the solar cell elements by means of solders that have different melting points, peeling off of the connection tabs due to remelting will not occur. This makes it possible to prevent the connection tabs from peeling off from the solar cell elements and output power of the solar cell module from dropping.

It is preferable that the solder layer with higher melting point be a solder layer that covers one of the surface electrode on the light-receiving surface of one of the solar cell elements and the back surface electrode on the non-light receiving surface of another one of the solar cell elements adjacent thereto that is connected to the connection tabs temporally earlier than the other one. This can prevent the connection tabs that have already been soldered from peeling off during the production.

The solder layer with higher melting point is preferably a solder layer that is substantially free of lead.

A solar cell module according to the present invention comprises: solar cell elements each including a semiconductor substrate, a surface electrode formed on a light-receiving surface of the semiconductor substrate and a back surface electrode formed on a non-light receiving surface of the semiconductor substrate; and connection tabs for interconnecting the surface electrodes on the light-receiving surface and the back surface electrodes on the non-light receiving surface of the solar cell elements, wherein the surface electrodes and the back surface electrodes are each connected to the connection tabs by means of a solder, and the connection tabs are provided with through holes at connection areas between the connection tabs and the surface electrodes or the back surface electrodes.

A solar cell module according to the present invention comprises a plurality of solar cell elements; connection tabs for interconnecting surface electrodes on a light-receiving surface and back surface electrodes on a non-light receiving surface of the solar cell elements; and a common connection line to which the connection tabs are connected by means of a solder, wherein the connection tabs or the common connection line are provided with through holes.

In addition, in a solar cell module according to the present invention, output wires connected to solar cell elements are connected to terminals of a terminal box, and through holes are provided in connection areas of the output wires or the terminals.

As described so far, through holes are provided at the respective connection areas, which permits visual inspection of the states of solder fillets that are formed inside the through holes.

In addition, by providing through holes, fillets are formed also in the interiors of the through holes. This enhances the area in which alloy layer is formed, allowing the joint strength to be improved. Also the thickness of the solder at the fillet portions enhances resistance to stress, allowing for improvement in durability against heat cycle.

Owing to the foregoing advantageous effects, production of a solar cell module with high reliability can be accomplished.

Additionally, the aforementioned connection areas provided with the through holes are preferably connected by means of a solder that is substantially free of lead.

### BRIEF DESCRIPTION OF THE DRAWINGS

FIG. 1 is a cross-sectional view showing one embodiment of a solar cell element according to the present invention.

FIG. 2(a) illustrates a step for interconnecting solar cell elements, showing a state prior to providing a connection tab 19 on the non-light receiving surface side.

FIG. 2(b) illustrates a step for interconnecting solar cell elements, showing a state after providing the connection tab 19 on the non-light receiving surface side.

FIG. 2(c) illustrates a step for interconnecting solar cell elements, showing a state where two solar cell elements 11a and 11b are connected together by means of a connection tab 17 on the light-receiving surface side.

FIG. 3 is a plan view of a solar cell module comprising solar cell elements connected to each other.

FIG. 4 is a cross-sectional view of a solar cell module.

FIG. 5 is a plan view of a solar cell element 11 with connection tabs 17 provided with through holes 18 on the light-receiving surface thereof.

FIG. 6(a) is a cross-sectional view showing a connection tab 17 with a through hole 18 soldered on an electrode 5 of a solar cell module.

FIG. 6(b) is a cross-sectional view showing a connection tab 17 without a through hole soldered on an electrode 5 of a solar cell module.

FIG. 7 is a schematic diagram of the wiring of a solar cell module.

FIG. 8 is a plan view showing a state of connection between connection tabs 17 and a transverse connection line 10 of a solar cell module.

FIG. 9 is a plan view showing a state of connection between an output wire 21 and a terminal 20 of a solar cell module.

### DETAILED DESCRIPTION OF THE INVENTION

The present invention will be hereinafter described in detail with reference to the appended drawings.

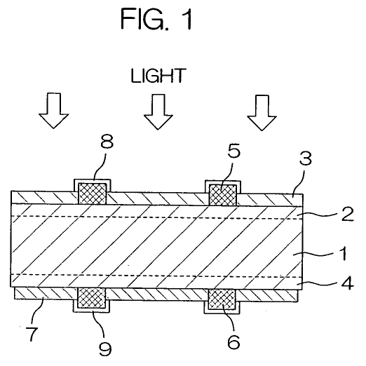

FIG. 1 is a cross-sectional view showing the structure of a solar cell element according to the present invention.

In FIG. 1, there are shown a semiconductor substrate 1, a diffusion layer 2 in the semiconductor substrate 1, an antireflective film formed on the surface of the semiconductor substrate 1, a BSF layer 4, a surface electrode 5 comprising bus bar electrodes on the light-receiving surface, a silver back surface electrode 6 comprising bus bar electrodes on the non-light receiving surface, an aluminum back surface electrode 7, a surface solder layer 8 formed on the surface electrode 5 and a back surface solder layer 9 formed on the silver back surface electrode 6.

Now, the structure and production process of the aforementioned solar cell element are described in detail.

First, the semiconductor substrate 1 comprises single crystal silicon, multi-crystalline silicon or the like. The semiconductor substrate 1 comprises silicon doped with a p-type impurity such as boron (B) at a concentration of 1×10¹⁶-1×10¹⁸ atoms/cm³ and has a specific resistance of about 1.5 Ωcm. When it is a single crystal silicon substrate, it is formed by crystal-pulling method or the like, and when it is a multi-crystalline silicon substrate, it is formed by casting method or the like. Multi-crystalline silicon is advantageous over single crystal silicon in view of production cost because it can be mass-produced. An ingot formed by crystal-pulling method or casting method is sliced into about 300 μm thick pieces and then cut to a size of 15 cm by 15 cm to form the semiconductor substrate 1.

Subsequently, the surface is etched to a minimum extent with use of hydrofluoric acid or hydrofluoric-nitric acid mixture so as to clean the cut surface of the semiconductor substrate 1.

Then the semiconductor substrate 1 is placed in a diffusion furnace and heated in phosphorus oxychloride (POCl₃) and the like so that phosphorus atoms are diffused into a surface region of the semiconductor substrate 1 to form an n-type diffusion layer 2 with a sheet resistance of about 30-300 Ω/square.

Subsequently, with the n-type diffusion layer on the surface side of the semiconductor substrate 1 being left, other parts of the n-type diffusion layer are removed, and then the substrate is cleaned with pure water. The removal of the n-type diffusion layer other than that on the surface side of the semiconductor substrate 1 can be effected by applying a resist film on the surface side of the semiconductor substrate 1 followed by etching with a solution of hydrofluoric-nitric acid mixture, and then by removing the resist film.

The antireflective film 3 is then deposited on the surface side of the semiconductor substrate 1. The antireflective film 3 comprises, for example, a silicon nitride film or the like. This is deposited, for example, by a plasma CVD process in which a mixture of silane (SiH₄) and ammonia (NH₄) gases is decomposed by a glow discharge that produces a plasma. In consideration of the difference in index of refraction between the antireflective film 3 and the semiconductor substrate 1, the antireflective film 3 is formed to have an index of refraction of about 1.8-2.3 and a thickness of about 500-1000 Å. The antireflective film 3 has a passivation effect when deposited, so that it has an effect to improve the electrical properties of the solar cell as well as the antireflection function.

Thereafter, an aluminum back surface electrode 7 is formed by applying paste composed mainly of aluminum on the back surface and firing it onto the back surface. During the firing, aluminum is diffused into the semiconductor substrate 1, resulting in formation of a BSF layer 4 as a p-type layer with high impurity concentration. In addition, an electrode material comprising silver is applied on the surface and back surface and fired onto them to form the surface electrode 5 and the silver back surface electrode 6.

The electrode material for the surface electrode 5 and the silver back surface electrode 6 is a material formed into a paste by adding an organic vehicle and glass frit in amounts of 10 to 30% by weight and 0.1 to 5% by weight, respectively, to 100% by weight of silver. The paste is printed by screen printing and fired at 600-800° C. for 1 to 30 minutes so as to adhere to the surfaces.

The organic vehicle employed in this process is a resin used for making a material in the form of powder into a paste, which may be, for example, cellulosic resin or acrylic resin. Since these resins are decomposed and sublimated at around 400° C., components thereof do not remain in the electrodes 5, 6 after the firing. The glass frit is used to provide the fired electrodes 5 and 6 with strength. The glass frit comprises an oxide of lead, boron, silicon or the like and has a softening point ranging from 300 to 600° C. Since a part of the glass frit remains in the electrodes 5, 6 after the firing and another part thereof is joined to silicon, it has the function to bond the electrodes 5, 6 and the semiconductor substrate 1 together.

The material for the surface electrode comprises one or plural kinds selected from Ti, P and compounds thereof, for example, oxides thereof with particle sizes of about 0.1 to 5 μm. The particle sizes of Ti, P, and compounds thereof are preferably in the range of 0.1-5 μm. At particle sizes less than 0.1 μm, the disperibiity in the electrode material is lowered, making it impossible to obtain sufficient electrode strength, which is undesirable. At particle sizes more than 5 μm, the screen printing performance deteriorates (line discontinuities, unevenness in line width occur) making it impossible to obtain sufficient electrode strength, which is also undesirable. The content thereof is preferably 0.05 to 5% by weight. Sufficient electrode strength cannot be obtained when the content thereof is less than 0.05% by weight, and the wire resistance of the electrode material increases when the content thereof is more than 5% by weight. Both cases are therefore undesirable.

The inclusion of one or plural kinds selected from P, Ti and compounds thereof in the electrode material allows an ohmic contact to be made in good order even when the electrode material is applied over the antireflective film 3, and enables production of a solar cell element with high electrode strength. This is because these materials act on the glass frit component included in the electrode material to promote the reaction between the antireflective film 3 and the glass frit. By this arrangement, sufficient ohmic contact and adhesion strength can be obtained even when the surface electrode 5 is formed by the firing through process.

The surfaces of the surface electrode 5 and back surface electrode 6 are coated with solders 8 and 9 for ensuring long-term reliability and connection of inner leads (connection tabs) for interconnecting solar cell elements in a later process.

The present invention is characterized in that the same elements as a plurality of elements included in the surface electrode 5 are included in the solder 8 that covers the surface electrode 5. This arrangement enhances the wettability between the electrode and solder, thereby improving the adhesion strength as compared to cases where only Ag is contained in the electrode and the solder.

Here, it is preferred that one of the plurality of the identical elements be Ag, and the other identical elements be one or more kinds selected from Ti, P, and compounds thereof, for example, oxides thereof. With the foregoing arrangement, the addition of these elements to the solder does not adversely affect the properties of the solder, while ensuring long-term reliability required for the solder.

One or more kinds selected from Ti, P, and compounds thereof are preferably included in the solder at 10-100 ppm. At less than 10 ppm, it is impossible to achieve the original object, that is, to enhance the wettability between the electrode and the solder thereby to improve the adhesion strength. At more than 100 ppm, brittleness of the solder increases, making it difficult to ensure long-term reliability and to connect the solder to inner leads in a later process.

Incidentally, although the solder exerts its effect particularly when used for coating the surface electrode 5, it can be used for coating the back surface electrode as well.

A solar cell module is an assembly constructed by electrically interconnecting a plurality of the solar cell elements described so far.

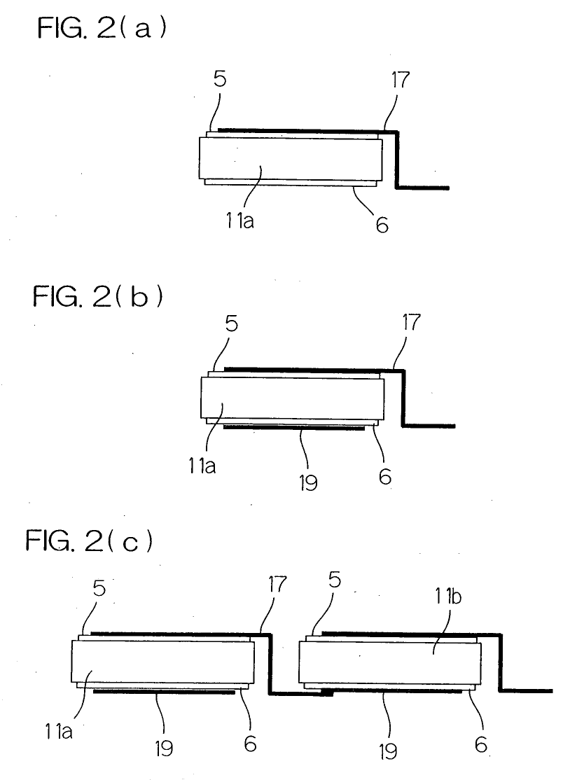

FIGS. 2(a)-2(c) are side views for illustrating states of connections in a solar cell module according to the present invention.

In FIGS. 2 (a) to 2(c), there are shown solar cell elements 11a, 11b, bus bar electrodes 5 on the light-receifing surface, connection electrodes (hereinafter referred to as the “connection tabs”) 17 on the light-receiving surface for interconnecting the solar cell elements, bus bar electrodes 6 on the non-light receiving surface, and connection tabs 19 on the non-light receivig surface.

FIG. 2(a) illustrates a state in which the connection tab 17 on the light-receiving surface is provided. FIG. 2(b) illustrates a state in which the connection tab 19 on the non-light receiving surface is further provided. FIG. 2 (c illustrates a state in which two solar cell elements 11a, 11b are interconnected by means of the connection tab 17 on the light-receiving surface.

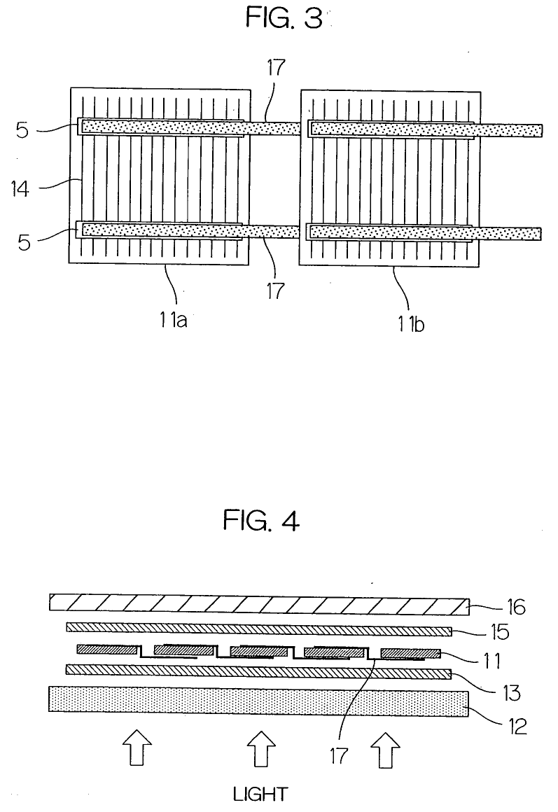

FIG. 3 is a plan view of a solar cell module. In FIG. 3, there are shown bus bar electrodes 5 on the light-receiving surface side of solar cell elements 11a and 11b, connection tabs 17 on the light-receiving side and finger electrodes 14 on the light-receiving surface side. Meanwhile, finger electrodes are formed also on the non-light receiving surface side (not diagramed).

Since the electrode area on the light-receiving surface needs to be as small as possible for greater light-receiving area, normally, the width of the bus bar electrode 5 is made smaller than that on the non-light receiving surface.

A multiplicity of the finger electrodes 14 are arranged parallel to the sides of the solar cell elements 11a and 11b for collecting light-generated carriers, which are formed with a width of, for example, about 0.2 mm. The bus bar electrodes 5 are two or so in number and arranged to perpendicularly cross the finger electrodes 14 for collecting electricity from the collected carriers, and formed to have a width of 2 mm or so for connection to the connection tabs 17.

When the solar cell elements 11a, 11b are series-connected to each other, the connection tabs 17 attached to the bus bar electrodes 5 on the light-receiving surface of the solar cell element 11a are connected to the connection tabs 19 on the non-light receiving surface of the adjacent solar cell element 11b. The connection between the connection tabs 17, 19 is accomplished by thermally melting the solder applied on the surfaces of the bus bar electrodes 5, 6 and the solder applied on the surfaces of the connection tabs 17, 19.

The connection tab 17 on the light-receiving surface comprises a copper foil with a thickness of about 100-300 μm whose entire surface is coated with a solder to a thickness of about 20-70 μm. The solder for coating the connection tab 17 should have a higher melting point than the solder used for the connection tab 19 on the non-light receiving surface. The optimum composition thereof would be, for example, 50% tin and 50% lead (melting point: 215° C.), 40% tin and 60% lead (melting point: 238° C.), or 30% tin and 70% lead (melting point: 258° C.).

Incidentally, in recent years, a great deal of attention has been focused on the use of lead-free solder in solar cell module production because lead is an environmentally hazardous substance. Many of such substantially lead-free solders have higher melting points than solders containing lead such as conventional eutectic solders. For example, a widely used, lead-free solder composed of 96.5% tin, 3% silver and 0.5% copper has a melting point of 220° C. as compared to the melting point 184° C. of an eutectic solder composed of 63% tin and 37% lead. Accordingly, such a substantially lead-free solder may be used as the solder for coating the surface of the connection tab 17 on the light-receiving surface.

The sum of the width of the connection tab 17 on the light-receiving surface and the width of the solder covering the tab should be the same as or smaller than the width of the bus bar electrode 5 on the light-receiving surface so as not to cast a shadow of itself on the light-receiving surface of the solar cell element. The length of the connection tab 17 is determined so that it overlaps almost the entire length of the bus bar electrode 5 on the light-receiving surface and covers the length of the interval between two solar cell elements 11a and 11b plus about 10-30 mm of the bus bar electrode 6 on the non-light receiving surface. The purpose of the connection tab 17 on the light-receiving surface overlapping almost the entire length of the bus bar electrode 5 on the light-receiving surface is to reduce the resistance component of the solar cell element.

When a common 150 mm square multi-crystalline silicon solar cell element is used, the width of the connection tab 17 on the light-receiving surface is about 1-3 mm, and the length thereof is about 160-180 mm.

The bus bar electrode 6 on the non-light receiving surface is usually wider than the bus bar electrode 5 on the light-receiving surface, and is about 4-6 mm wide, for example. The connection tab 19 on the non-light receiving surface comprises a copper foil with a thickness of about 50-150 μm whose entire surface is coated with a solder to a thickness of about 20-70 μm. The solder for coating the connection tab 19 has a lower melting point than the solder used for the connection tab 17 on the light-receiving surface. The optimum composition thereof would be, for example, 63% tin and 37% lead (melting point: 184° C.) or 60% tin and 40% lead (melting point: 190° C.).

The width of the connection tab 19 on the non-light receiving surface is almost the same as that of the bus bar electrode 6 on the non-light receiving surface, and the length thereof is almost the same as or somewhat smaller than the bus bar electrode 6 on the non-light receiving surface. The purpose of connecting the connection tab 19 on the non-light receiving surface is to reduce the electrical resistance of the electrode. When a common 150 mm square multi-crystalline silicon solar cell element is used, the width is about 4-6 mm and the length is about 130-150 mm.

The connection between solar cell elements according to the present invention is carried out as follows. First, as shown in FIG. 2(a), a connection tab 17 on the light-receiving surface is placed on a bus bar electrode 5 on the light-receiving surface of the solar cell element 11a. While the connection tab 17 on the light-receiving surface is pressed with a pressing pin (not shown), hot air is sprayed so that the solders on the bus bar electrode 5 and the connection tab 17 on the light-receiving surface are both melted to cause the both parts to be connected together.

Then, as shown in FIG. 2(b), a connection tab 19 on the non-light receiving surface is placed at a predetermined position on a bus bar electrode 6 on the non-light receiving surface of the solar cell element 11a with the connection tab 17 on the light-receiving surface attached on the bus bar electrode 5 on the light-receiving surface. While the connection tab 19 on the non-light receiving surface is pressed with a pressing pin (not shown), hot air is sprayed so that the solders on the bus bar electrode 6 on the non-light receiving surface and the connection tab 19 on the non-light receiving surface are both melted to cause the both parts to be connected together.

In this case, since the solder on the surface of the connection tab 17 on the light-receiving surface has a higher melting point than the solder on the surface of the connection tab 19 on the non-light receiving surface, the connection tab 17 on the light-receiving surface does not remelt even when heat is applied to attach the connection tab 19 on the non-light receiving surface nor peel off from the bus bar electrode 5 on the light-receiving surface.

Subsequently, as shown in FIG. 2(c), one end of the connection tab 17 on the light-receiving surface is disposed at a predetermined position on the connection tab 19 on the non-light receiving surface of the adjacent solar cell element 11b, and while the connection tab 19 is pressed with a pressing pin (not shown), hot air is sprayed so that the solders on the connection tab 17 on the light-receiving surface and the connection tab 19 on the non-light receiving surface are both melted to cause the both parts to be connected together. Because the overlapping length of the connection tab 17 and the connection tab 19 is about 10 mm, and they are joined together by pinpoint spraying with hot air within a short period, the solders solidify before the heat propagates to other regions. Therefore, problems such as separation of the connection tab 17 from the connection tab 19 will not arise.

While in the foregoing process of connecting the solar cell elements 11a, 11b together, the connection tab 17 on the light-receiving surface is first connected to the bus bar electrode 5 on the light receiving surface of the solar cell element 11a, and then the connection tab 19 on the non-light receiving surface is connected to the bus bar electrode 6 on the non-light receiving surface, it is also possible to connect the connection tab 19 on the non-light receiving surface to the bus bar electrode 6 on the non-light receiving surface first, and then connect one end of the connection tab 17 on the light-receiving surface thereto. In this case, the solder used for the connection tab 19 on the non-light receiving surface should have a higher melting point than the solder used for the connection tab 17 on the light-receiving surface.

FIG. 4 is a cross-sectional view showing one example of the structure of a solar cell module fabricated in the foregoing manner. In FIG. 4, there are shown a translucent substrate 12, fillers 13, 15, a plurality of solar cell elements 14 connected by means of connection tabs 17, and a back surface component 16.

For the translucent substrate 12, a clear tempered glass or the like with a thickness of about 3-5 mm is commonly used. The solar cell element 11 comprises a single crystal silicon substrate or multi-crystalline silicon substrate with a thickness on the order of 0.3 mm, and its size is, for example, approximately 150 mm square in the case of a multi-crystalline silicon solar cell. When a solar cell module is produced, the electrodes of the solar cell element 11 are connected to connection tabs 17 comprising a copper foil plated with a solder, and further, a plurality of solar cell elements 11 are connected in series/parallel by means of the connection tabs 17 so that a predetermined electric power can be extracted from the solar cell module.

For the fillers 13, 15, materials composed mainly of ethylene vinyl acetate copolymer (EVA) or polyvinyl butyral (PVB) are commonly used. The back surface component 16 comprises a material with weatherability such as fluorine-containing resin with an aluminum foil held therein to prevent moisture penetration.

In the production of a solar cell module, as shown in FIG. 4, stacked components as a whole are subjected to heat in a device called laminator and pressed to be formed into an integrated structure. A module frame (not shown) made of aluminum or the like is attached to the integrated structure with four sides thereof being secured with screws, and in addition, a terminal box (not shown) for delivering electric power output from the solar cell module to an external circuit is fixed to the module with an adhesive. Thus, the entire solar cell module is completed.

The type of the solar cell element according to the present invention is not limited to crystal solar cells such as single crystal silicon solar cells and multi-crystalline silicon solar cells, but may be thin film solar cells so long as the solar cell module thereof is constructed such that a plurality of solar cell elements are disposed on a non-light receiving surface of a translucent substrate, and the plurality of the solar cell elements are electrically interconnected by means of connection tabs.

Now, embodiments with connection tabs provided with through holes will be described.

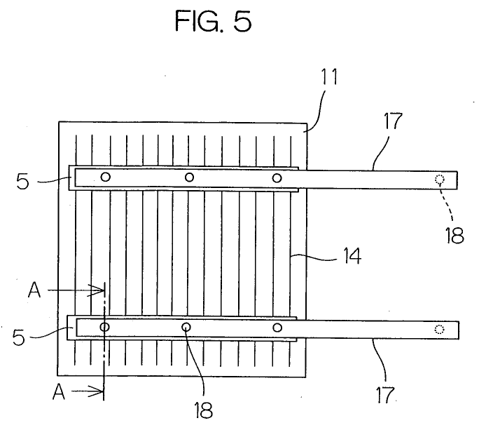

FIG. 5 is a plan view of a solar cell element 11 having connection tabs 17 connected to the light-receiving surface thereof. The connection tabs 17 are provided with through holes 18. FIG. 5 shows a solar cell element 11, bus bar electrodes 5, finger electrodes 14, connection tabs 17, and through holes 18 penetrating the connection tabs 17 from front to rear.

The bus bar electrodes 5 and finger electrodes 14 are formed by screen-printing silver paste or the like. Almost the entire surfaces of the bus bar electrodes 5 are coated with a solder as described above for protection thereof and ease of connection tab attachment.

As mentioned previously, the connection tab 17 comprises a copper foil with a thickness of about 100-300 μm whose entire surface is coated with a solder to a thickness of about 20-70 μm. The width thereof should be the same as or smaller than the width of the bus bar electrode 5 so as not to cast a shadow of itself on the light-receiving surface of the solar cell element. The length of the connection tab 17 is determined so that it overlaps almost the entire length of the bus bar electrode 5 and covers the predetermined interval between the solar cell elements plus about 10-50 mm of the bus bar electrode (not shown) on the non-light receiving surface of the adjacent solar cell element. When a common 150 mm square multi-crystalline silicon solar cell element is used, the width of the connection tab 17 is about 1-3 mm, and the length thereof is about 160-210 mm. The purpose of the connection tab 17 overlapping almost the entire length of the bus bar electrode 5 on the light-receiving surface is to reduce the resistance component of the solar cell element.

The through holes 18 are preliminarily provided in the area where the connection tab 17 is connected to the bus bar electrode 5. Likewise, the through hole 18 is preliminarily provided in the area where the connection tab 17 is connected to the bus bar electrode 6 on the non-light receiving surface of the adjacent solar cell element.

When a common 150 mm square multi-crystalline silicon solar cell element is used, two to five through holes 18 are provided in the area to be connected to the bus bar electrode 5, and one to three through holes 18 are provided in the area to be connected to the bus bar electrode 6 on the non-light receiving surface of the adjacent solar cell element by punching or the like. The optimum diameter of the through hole 18 is ¼ to ½ of the width of the connection tab 17. The shape of the through hole 18 is not limited to circular, but may be elliptic, square, rectangular and other polygonal shapes.

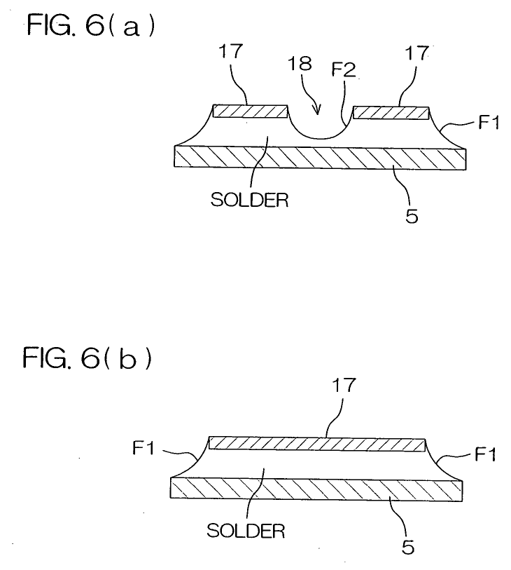

FIG. 6(a) is a cross-sectional view of a portion including a through hole formed in a connection tab soldered on a bus bar electrode (a view taken along the line A-A of FIG. 5). FIG. 6(a) shows a bus bar electrode 5 of a solar cell element, a connection tab 17, a through hole 18 and fillets “F1” “F2” that are formed by a solder, which are collectively referred to as the “fillet F”. Fillet F is formed also at end portions of the connection tab 17 and the inside of the through hole 18 as shown in FIG. 6(a). Fillets formed at the end portions of the connection tab 17 are denoted by F1, and the fillet formed inside the through hole 18 is denoted by F2.

FIG. 6(b) is a cross-sectional view showing a connection tab without having a through hole soldered on an electrode of a solar cell element. In FIG. 6(b), the surface of the electrode 5 of the solar cell element is coated with a solder, and fillets F1 having a generally triangular cross section are formed between end portions of the connection tab 17 and the electrode 5 of the solar cell element. However, since the connection tab 17 is not provided with a through hole, it is impossible to observe the fillet F2 formed inside the through hole 18. This has the drawback that the state of soldering between the connection tab 17 and the electrode 5 of the solar cell element cannot be judged from the exterior appearance.

In the present invention, since the connection tab 17 is provided with through holes 18, fillets F2 formed inside the through holes 18 can be observed. Based upon the presence or absence, the sizes and configurations of fillets F1 formed at end portions of the connection tab 17 and fillets F2 formed inside the through holes 18, the state of soldering in the vicinity of the central area of the bus bar electrode 5 can be judged by visual observation. That is, if fillets F1 and F2 are formed covering the bus bar electrode 5 at end portions of the connection tab 17 and the interiors of the through holes, the state of soldering can be judged as good, and if fillets F1 and F2 are not formed or the sizes thereof are small, the state of soldering can be judged as imperfect.

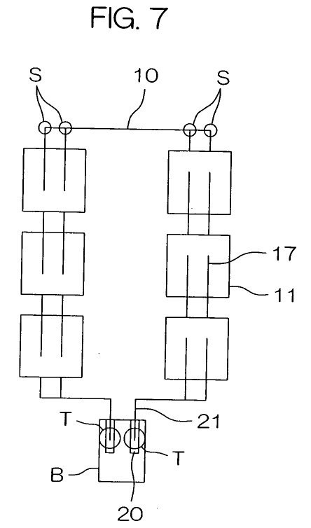

FIG. 7 is a schematic diagram of wiring inside a solar cell module. FIG. 7 shows solar cell elements 11, connection tabs 17, a transverse connection line 10, connection points S between the connection tabs 17 and the transverse connection line 10, output wires 21 from the solar cell elements, a terminal box B and terminals 20 inside the terminal box.

In many cases, solar cell elements 11 are fabricated using single crystal silicon substrate or multi-crystalline silicon substrate as mentioned above. Generally, the connection tabs 17 are obtained by cutting a solder-coated copper foil into pieces of predetermined lengths. The transverse connection line 10 is provided for adjustment of longitudinal and transverse dimensions of the solar cell module, and also generally comprises a solder-coated copper foil. The output wires 21 from the solar cell elements connect the solar cell elements 11 to the terminals 20 inside the terminal box B, and also for the output wires, a solder-coated copper foil is commonly used. The terminals 20 inside the terminal box B are connected to the output wires 21 from the solar cell elements 11 and a cable of an external circuit (not shown). A copper plate coated with a solder is used for the terminals 20 inside the terminal box B.

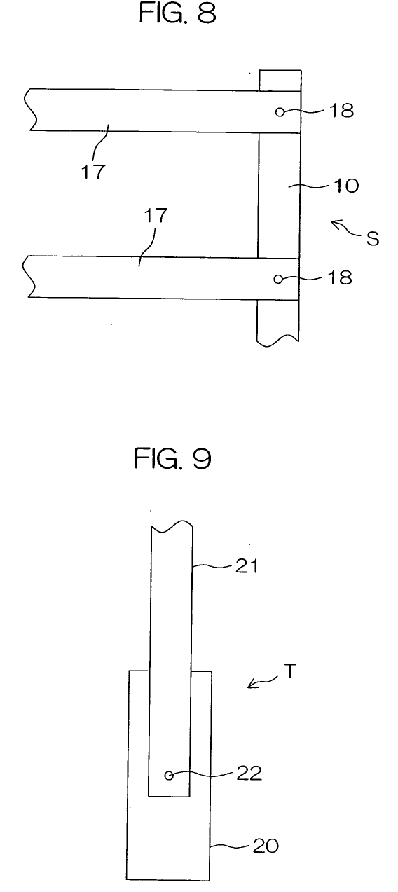

FIG. 8 illustrates a state of connection between connection tabs 17 and a transverse connection line 10 provided in a solar cell module. In FIG. 8, there are shown connection tabs 17, a transverse connection line 10 and through holes provided in the connection tabs 17.

The transverse connection line 10 comprises a copper foil with a width of about 3-10 mm and a thickness of 100-300 μm whose entire surface is coated with a solder. The through holes 18 provided in the connection tabs 17 are formed by punching or the like, and the optimum diameter thereof is ¼ to ½ of the width of the connection tab 17. The shape of the through holes 18 is not limited to circular, but may be elliptic, square, rectangular, and other polygonal shapes.

The connection between the connection tabs 17 and the transverse connection line 10 is carried out such that a connection tab 17 previously provided with a through hole 18 is placed on the connection line 10 and while the connection tab 17 is pressed with a pressing pin (not shown), hot air is sprayed so that the solders on the connection line 10 and the connection tab 17 are both melted.

Also in the case of the connection between the connection tabs 17 and the connection line 10, providing through holes 18 in the connection areas of the connection tabs 17 enables visual inspection of the state of soldering by observing fillets at the through holes 18.

While an example in which connection tabs 17 are soldered on the transverse connection line 10 is described in FIG. 8, when the transverse connection line 10 is soldered on the connection tabs 17, the transverse connection line 10 may be provided with through holes.

FIG. 9 illustrates a state of connection between an output wire from a solar cell module and a terminal inside a terminal box. FIG. 9 shows a terminal 20 inside a terminal box, an output wire 21 from a solar cell element and a through hole 22 provided in the output wire 21 from the solar cell element.

The terminal 20 comprises a copper plate with a thickness of about 1-3 mm, a width of about 5-20 mm and a length of about 30-70 mm whose surface is coated with a solder. The output wire 21 from the solar cell element comprises a copper foil with a width of about 2-10 mm and a thickness of about 100-300 μm whose surface is coated with a solder. The through hole 22 provided in the output wire 21 is formed by punching or the like in the area where the output wire 21 is connected to the terminal 20, which is one or two in number. The optimum diameter thereof is ¼ to ½ of the width of the output wire 21. The shape of the through hole 22 is not limited to circular, but may be elliptic, square, rectangular, and other polygonal shapes.

The connection between the terminal 20 and the output wire 21 is carried out such that the output wire 21 previously provided with the through hole 22 at a predetermined position is placed on the terminal 20 and while the output wire 21 is pressed with a pressing pin (not shown), hot air is sprayed or soldering iron is applied so that the solders on the terminal 20 and the output wire 21 are both melted.

Also in the case of the connection between the terminal 20 and the output wire 21, providing the through hole 22 in the connection area of the output wire 21 enables visual inspection of the state of soldering by observing the fillet at the through hole 22. While an example in which the output wire 21 is soldered onto the terminal 20 is described in FIG. 9, when the terminal 20 is soldered onto the output wire 21, the terminal 20 may be provided with a through hole 22.

In recent years, a great deal of attention has been focused on the use of lead-free solder in solar cell module production because lead is an environmentally hazardous substance. Many of such substantially lead-free solders, however, have higher melting points and lower wettability than solders containing lead such as conventional eutectic solders. For example, an eutectic solder composed of 63% tin and 37% lead has a melting point of 183° C., and the value of spread test indicating the wettability is 91.5%. In comparison, a widely used lead-free solder composed of 96.5% tin, 3% silver, and 0.5% copper has a melting point of 220° C., and the value of spread test is 76.3%. For this reason, when a substantially lead-free solder is used, the conditions for soldering such as temperature and time need to be carefully controlled, as well as the finished state of soldering needs to be strictly checked. The present invention can effectively utilize such substantially lead-free solders by permitting visual inspection of the state of soldering based on the states of solder fillets formed inside the through holes provided at connection areas.

Meanwhile, it should be understood that the present invention is not limited to the foregoing embodiments, and various improvements and modifications may be made to the foregoing embodiments within the scope of the present invention. For example, the solar cell element is not limited to crystal solar cells such as single crystal solar cells and multi-crystalline silicon solar cells, but may be of any kind so long as it can constitute a solar cell module whose interior electrical connections are accomplished by soldering with use of solder-coated metal foils and the like.

What is claimed is:

1. A solar cell element comprising:
a semiconductor substrate;
an antireflective film formed on a light-receiving surface of the semiconductor substrate;
a surface electrode formed on the light-receiving surface of the semiconductor substrate;
a back surface electrode formed on a non-light receiving surface of the semiconductor substrate;
a first solder layer covering the surface electrode; and
a second solder layer covering the back surface electrode, wherein two or more elements selected from a plurality of elements included in the surface electrode and two or more elements selected from elements included in the first solder layer are each identical to one another.

2. The solar cell element according to claim 1, wherein one of the two or more elements is Ag, and the other elements are one or more kinds selected from Ti, P, and compounds thereof.

3. The solar cell element according to claim 2, wherein said the other elements are included in the first solder layer at 10-100 ppm.

4. The solar cell element according to claim 2, wherein said the other elements are included in the surface electrode at 0.05-5% by weight.

5. A solar cell module comprising:
solar cell elements each including a semiconductor substrate, a surface electrode formed on a light-receiving surface of the semiconductor substrate and a back surface electrode formed on a non-light receiving surface of the semiconductor substrate; and
connection tabs for interconnecting the surface electrode on the light-receiving surface and the back surface electrode on the non-light receiving surface of the solar cell elements,
wherein a first solder layer for connecting the surface electrode to the connection tab on the light-receiving surface and a second solder layer for connecting the back surface electrode to the connection tab on the non-light receiving surface have different melting points.

6. The solar cell module according to claim 5, wherein the solder layer with higher melting point is a solder layer that covers one of the surface electrode on the light-receiving surface of one of the solar cell elements and the back surface electrode on the non-light receiving surface of another one of the solar cell elements adjacent thereto that is connected to the connection tabs temporally earlier than the other one.

7. The solar cell module according to claim 6, wherein the solder layer with higher melting point is substantially free of lead.

8. The solar cell module according to claim 5, wherein the connection tabs are provided with through holes at connection areas between the connection tabs and the surface electrodes or the back surface electrodes.

9. The solar cell module according to claim 5, wherein the connection tabs are connected to a common connection line by means of a solder, and the connection tabs are provided with through holes at connection areas between the connection tabs and the common connection line.

10. The solar cell module according to claim 5, wherein the connection tabs are connected to a common connection line by means of a solder, and the common connection line is provided with through holes at connection areas between the common connection line and the connection tabs.

11. The solar cell module according to claim 5, wherein output wires connected to the solar cell elements are connected to terminals of a terminal box by means of a solder, and the output wires are provided with through holes at connection areas between the output wires and the terminals.

12. The solar cell module according to claim 5, wherein output wires connected to the solar cell elements are connected to terminals of a terminal box by means of a solder, and the terminals are provided with through holes at connection areas between the terminals and the output wires.

13. A solar cell module comprising:
solar cell elements each including a semiconductor substrate, a surface electrode formed on a light-receiving surface of the semiconductor substrate and a back surface electrode formed on a non-light receiving surface of the semiconductor substrate; and
connection tabs for interconnecting the surface electrodes on the light-receiving surface and the back surface electrodes on the non-light receiving surface of the solar cell elements,
wherein the surface electrodes and the back surface electrodes are each connected to the connection tabs by means of a solder, and the connection tabs are provided with through holes at connection areas between the connection tabs and the surface electrodes or the back surface electrodes.

14. The solar cell module according to claim 13, wherein the connection areas of the connection tabs are connected to the surface electrodes or the back surface electrodes by means of a solder that is substantially free of lead.

15. A solar cell module comprising:
a plurality of solar cell elements;
connection tabs for interconnecting surface electrodes on a light-receiving surface and back surface electrodes on a non-light receiving surface of the solar cell elements; and
a common connection line to which the connection tabs are connected by means of a solder,
wherein the connection tabs are provided with through holes at connection areas between the connection tabs and the common connection line.

16. The solar cell module according to claim 15, wherein the connection areas of the connection tabs are connected to the common connection line by means of a solder that is substantially free of lead.

17. A solar cell module comprising:
a plurality of solar cell elements;
connection tabs for interconnecting surface electrodes on a light-receiving surface and back surface electrodes on a non-light receiving surface of the solar cell elements; and
a common connection line to which the connection tabs are connected by means of a solder,
wherein the common connection line is provided with through holes at connection areas between the common connection line and the connection tabs.

18. The solar cell module according to claim 17, wherein the connection areas of the common connection line are connected to the connection tabs by means of a solder that is substantially free of lead.

19. A solar cell module comprising;
solar cell elements;
output wires connected to the solar cell elements; and
a terminal box including terminals to which the output wires are connected,
wherein the output wires are provided with through holes at connection areas between the output wires and the terminals.

20. The solar cell module according to claim 19, wherein the connection areas of the output wires are connected to the terminals by means of a solder that is substantially free of lead.

21. A solar cell module comprising;
solar cell elements;
output wires connected to the solar cell elements; and
a terminal box including terminals to which the output wires are connected,
wherein the terminals are provided with through holes at connection areas between the terminals and the output wires.

22. The solar cell module according to claim 21, wherein the connection areas of the terminals are connected to the output wires by means of a solder that is substantially free of lead.
